(19) United States
(12) Patent Application Publication
(10) Pub. No.: US 2016/0035799 A1
(43) Pub. Date: Feb. 4, 2016

(54) DISPLAY UNIT OF DISPLAY PANEL

(71) Applicant: CHUNGHWA PICTURE TUBES, LTD., Taoyan County (TW)

(72) Inventor: HSI-MING CHANG, TAOYUAN COUNTY (TW)

(21) Appl. No.: 14/500,275

(22) Filed: Sep. 29, 2014

(30) Foreign Application Priority Data
Jul. 30, 2014 (TW) 103213496

(51) Int. Cl. H01L 27/32

(52) U.S. Cl. CPC H01L 27/3216; H01L 27/3213

(57) ABSTRACT

A display unit of a display panel includes three pixels having different colors. Each pixel has a color sub-pixel and a transparent sub-pixel, both approximately arranged in one column along a first direction. Each pixel has a ratio defined by the area of the color sub-pixel divided by the area of the corresponding transparent sub-pixel. The three pixels are arranged in one row along a second direction, and the ratios of the three pixels are different from each other. Thus, the light transmittance of the display unit can be increased, and the area of the color sub-pixel for each pixel can be adjusted according to lighting efficiency.

### BACKGROUND OF THE INVENTION

1. Field of the Invention

The invention relates to a display panel; in particular, to a display unit of a display panel.

2. Description of Related Art

The technology of transparent display panel has been actively evolving. The transparent display panel has a certain degree of light transmittance, in order to clearly show the rear background of the transparent display panel. Furthermore, the transparent display panel is suitable for a variety of applications, such as windows of buildings, car windows, and shop windows. In addition to the original transparent display function, the transparent display panel also has the developing potential for being information displays in the future, thereby receiving attention in the market.

However, the way of increasing the light transmittance of the display panel today only adds a transparent pixel adjacent to the red pixel display unit, the green pixel, and the blue pixel. Accordingly, after deducting traces of shading area, the light transmittance of each display unit is at around 20%. Thus, how to effectively improve the light transmittance of the display panel has become one of the important topics of the industry.

### SUMMARY OF THE INVENTION

The invention provides a display unit of a display panel for increasing light transmittance effectively.

One embodiment of the invention provides a display unit of a display panel, comprising: a first pixel having a first color sub-pixel and a first transparent sub-pixel, both approximately arranged in one column along a first direction, wherein the first pixel has a first ratio defined by the area of the first color sub-pixel divided by the area of the first transparent sub-pixel; a second pixel having a second color sub-pixel and a second transparent sub-pixel, both approximately arranged in one column along the first direction, wherein the second pixel has a second ratio defined by the area of the second color sub-pixel divided by the area of the second transparent sub-pixel; and a third pixel having a third color sub-pixel and a third transparent sub-pixel, both approximately arranged in one column along the first direction, wherein the third pixel has a third ratio defined by the area of the third color sub-pixel divided by the area of the third transparent sub-pixel; wherein the first pixel, the second pixel, and the third pixel are adjacent to each other and arranged in one row along a second direction, and wherein the first ratio, the second ratio, and the third ratio are different from each other.

The embodiment of the invention also provides a display unit of a display panel, comprising: a first pixel having a first color sub-pixel and a first transparent sub-pixel, both approximately arranged in one column along a first direction, wherein the first pixel has a first ratio defined by the area of the first color sub-pixel divided by the area of the first transparent sub-pixel; a second pixel having a second color sub-pixel and a second transparent sub-pixel, both approximately arranged in one column along the first direction, wherein the second pixel has a second ratio defined by the area of the second color sub-pixel divided by the area of the second transparent sub-pixel; a third pixel having a third color sub-pixel and a third transparent sub-pixel, both approximately arranged in one column along the first direction, wherein the third pixel has a third ratio defined by the area of the third color sub-pixel divided by the area of the third transparent sub-pixel; and a transparent pixel having an area greater than each one of the area of the first transparent sub-pixel, the area of the second transparent sub-pixel, and the area of the third transparent sub-pixel; wherein the first pixel, the second pixel, the third pixel, and the transparent pixel are adjacent to each other and arranged in one row along a second direction perpendicular to the first direction, and the first ratio, the second ratio, and the third ratio are approximately the same.

The embodiment of the invention further provides a display unit of a display panel, comprising a first pixel, a second pixel, a third pixel, and a transparent pixel, wherein the first pixel has a first color sub-pixel and a first transparent sub-pixel, both approximately arranged in one column along a first direction, the area of the transparent pixel is greater than the area of the first transparent sub-pixel, wherein the first pixel, the second pixel, the third pixel, and the transparent pixel are adjacent to each other and arranged in one row along a second direction perpendicular to the first direction.

In summary, the display unit of the display panel in the invention can effectively increase the light transmittance by forming the transparent sub-pixel in the pixel. Moreover, because the color sub-pixels of the display unit respectively have different lighting properties, such that the color sub-pixel capable of higher lighting efficiency can be provided with smaller area, and the area of the corresponding transparent sub-pixel can be increased, the invention has high transmittance and high display quality.

### BRIEF DESCRIPTION OF THE DRAWINGS

FIG. 1A is a plan view showing a display panel according to one embodiment of the invention;

FIG. 1B is a cross-sectional view showing part of the display panel of FIG. 1A along section line 1B-1B;

FIG. 1C is a cross-sectional view showing part of the display panel of FIG. 1A along section line 1C-1C;

FIG. 1D is a cross-sectional view showing part of the display panel of FIG. 1A along section line 1D-1D;

FIG. 1E is a cross-sectional view showing part of the display panel of FIG. 1A along section line 1E-1E;

FIG. 2 is a plan view showing the display panel according to another implementation of the embodiment of the invention; and

FIG. 3 is a plan view showing the display panel according to the other implementation of the embodiment of the invention.

### DETAILED DESCRIPTION OF THE PREFERRED EMBODIMENTS

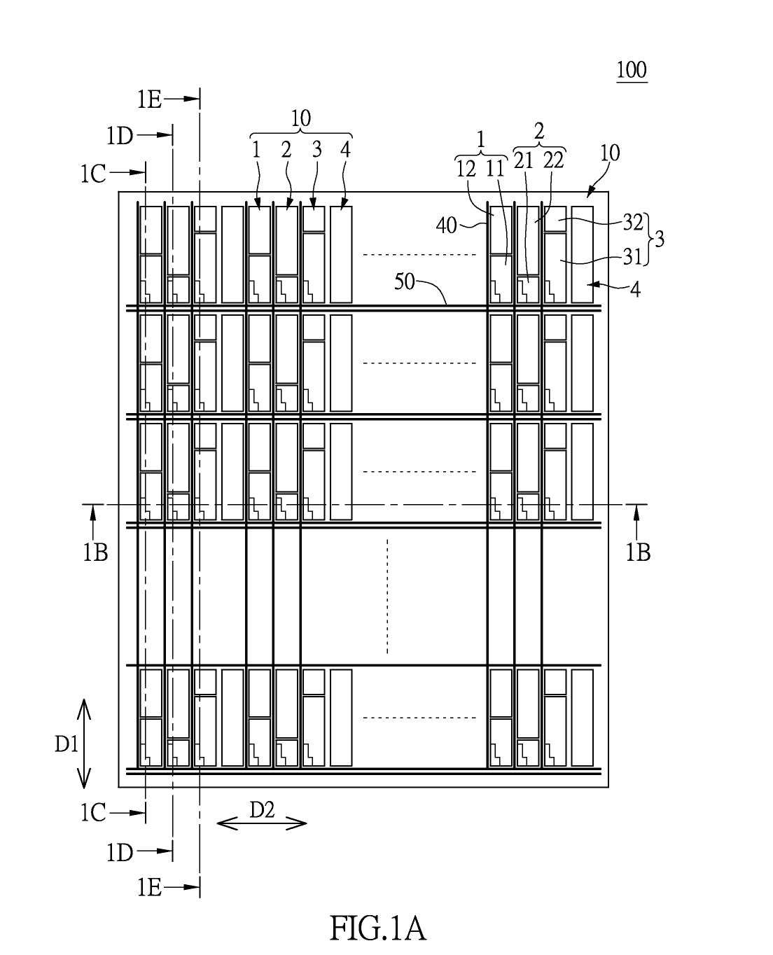

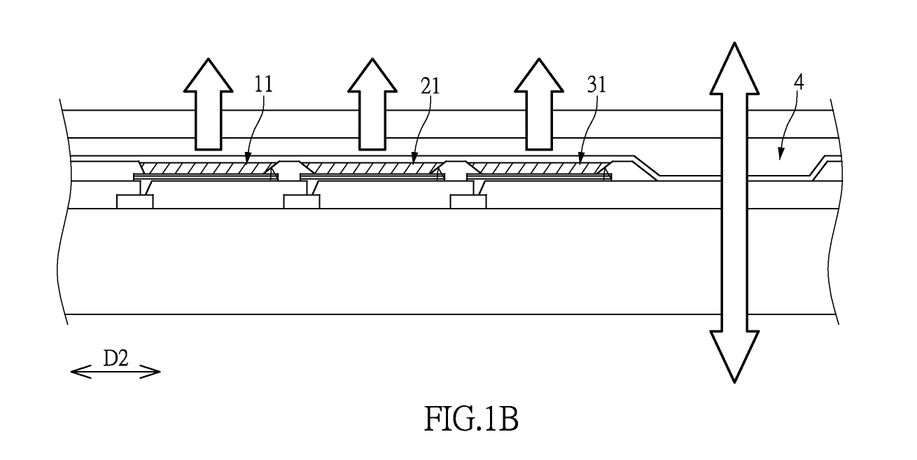

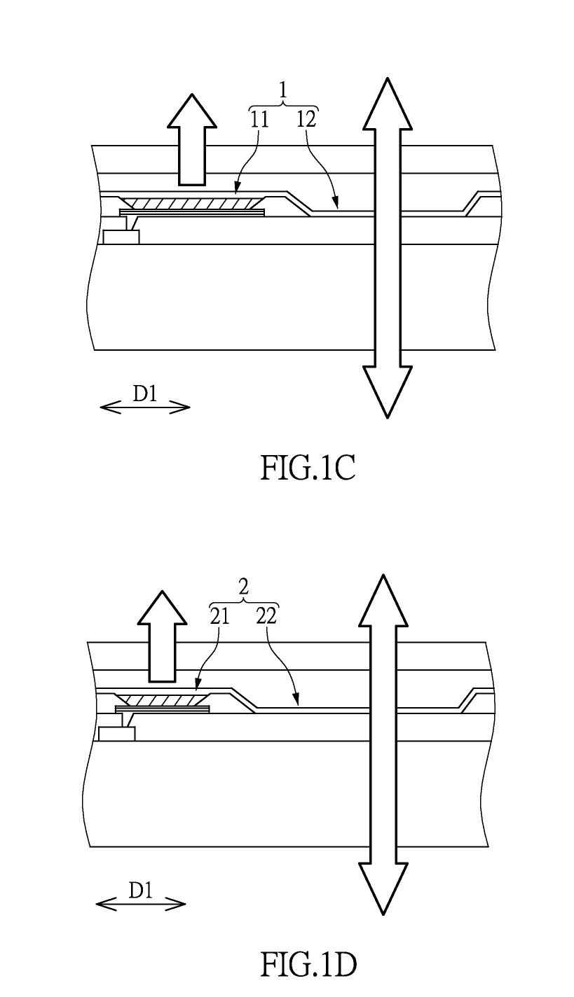

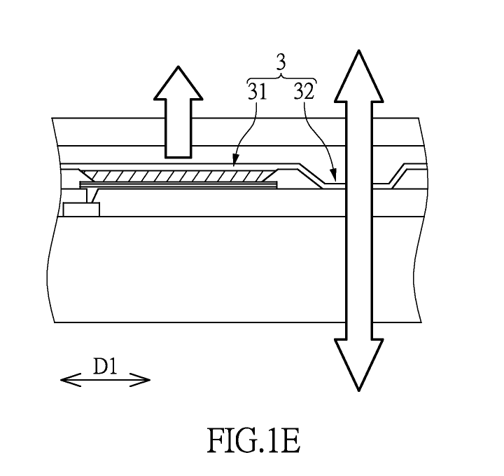

Please refer to FIGS. 1A through 3, which show an embodiment of the invention. References are hereunder made to the detailed descriptions and appended drawings in connection with the invention.

As shown in FIG. 1A, the embodiment provides a display panel 100, such as an OLED display panel, but the display panel 100 is not limited to. The display panel 100 includes a plurality of display units 10 arranged in a crisscross arrangement to be a matrix type. The display units 10 are approximately arranged along a first direction D1 and a second direction D2, in which both are perpendicular to each other. Moreover, the first direction D1 in the embodiment is approximately parallel to the data line 40 of the display panel 100, and the second direction D2 is approximately parallel to the scan line 50 of the display panel 100.

In the embodiment, the display units 10 are approximately the same, such that the following description discloses just one of the display units 10. Moreover, the following description explains the relationship of the pixels of the display unit 10.

Please refer to FIG. 1A, and FIGS. 1B through 1E. The display unit 10 includes a first pixel 1, a second pixel 2, a third pixel 3, and a transparent pixel 4. Each one of the first pixel 1, the second pixel 2, the third pixel 3, and the transparent pixel 4 in the embodiment is approximately an elongated shape, which is approximately parallel to the first direction D1. Specifically, lengths of the first pixel 1, the second pixel 2, the third pixel 3, and the transparent pixel 4 corresponding to the first direction D1 are approximately identical, and widths of the first pixel 1, the second pixel 2, the third pixel 3, and the transparent pixel 4 corresponding to the second direction D2 are approximately identical. In other words, the first pixel 1, the second pixel 2, the third pixel 3, and the transparent pixel 4 have the same area, but the invention is not limited thereto. Moreover, the first pixel 1, the second pixel 2, the third pixel 3, and the transparent pixel 4 are adjacent to each other and arranged in one row along the second direction D2.

The first pixel 1 includes a first color sub-pixel 11 and a first transparent sub-pixel 12. The first color sub-pixel 11 and the first transparent sub-pixel 12 are approximately arranged in one column along the first direction D1. The first pixel 1 has a first ratio defined by the area of the first color sub-pixel 11 divided by the area of the first transparent sub-pixel 12. Additionally, the “ratio” in the embodiment means “the area of color sub-pixel” divided by “the area of transparent sub-pixel”.

The second pixel 2 includes a second color sub-pixel 21 and a second transparent sub-pixel 22. The second color sub-pixel 21 and the second transparent sub-pixel 22 are approximately arranged in one column along the first direction D1. The second pixel 2 has a second ratio defined by the area of the second color sub-pixel 21 divided by the area of the second transparent sub-pixel 22.

The third pixel 3 includes a third color sub-pixel 31 and a third transparent sub-pixel 32. The third color sub-pixel 31 and the third transparent sub-pixel 32 are approximately arranged in one column along the first direction D1. The third pixel 3 has a third ratio defined by the area of the third color sub-pixel 31 divided by the area of the third transparent sub-pixel 32.

Specifically, the display panel 100 in the embodiment is an OLED display panel for example, so that each one of the first color sub-pixel 11, the second color sub-pixel 21, and the third color sub-pixel 31 has an active component, an anode layer, an organic lighting layer, and a cathode layer. However, although the display panel 100 in the embodiment is an OLED display panel for example, the display panel 100 of the invention does not exclude another kind of display panel. For example, when the display panel 100 is an electrophoretic display panel, each one of the first color sub-pixel 11, the second color sub-pixel 21, and the third color sub-pixel 31 has an active component, a pixel electrode, an electrophoretic display layer, and an opposing electrode.

The first transparent sub-pixel 12, the second transparent sub-pixel 22, the third transparent sub-pixel 32, and the transparent pixel 4 are provided without carrying any display component, thus each one of the first transparent sub-pixel 12, the second transparent sub-pixel 22, the third transparent sub-pixel 32, and the transparent pixel 4 may have only a conductive line (e.g., transparent cathode layer) for transmitting signal or is provided without any conductive line, but the invention is not limited thereto.

The first transparent sub-pixel 12, the second transparent sub-pixel 22, the third transparent sub-pixel 32, and the transparent pixel 4 are provided without carrying any display component, thereby having a good transmittance or transparency. Therefore, when the display unit 10 of the display panel 100 is turned off, the first transparent sub-pixel 12, the second transparent sub-pixel 22, the third transparent sub-pixel 32, and the transparent pixel 4 cause the display unit 10 to be transparent, thereby allowing the user to see the rear background of the display unit 10.

Moreover, the area of each one of the first transparent sub-pixel 12, the second transparent sub-pixel 22, and the third transparent sub-pixel 32 is adjustable according to the designer's request for having high transmittance and high display quality. In more detail, because the first color sub-pixel 11, the second color sub-pixel 21, and the third color sub-pixel 31 respectively have different lighting properties, the color sub-pixel capable of higher lighting efficiency needs to be provided with smaller area, and the area of the corresponding transparent sub-pixel can be increased. On the other hand, the color sub-pixel capable of lower lighting efficiency needs to be provided with larger area, and the area of the corresponding transparent sub-pixel can be decreased. Thus, the adjustment of the area of the sub-pixels causes the first ratio, the second ratio, and the third ratio to be different from each other.

In the embodiment, the first color sub-pixel 11 is a red color sub-pixel, the second color sub-pixel 21 is a green color sub-pixel, and the third color sub-pixel 31 is a blue color sub-pixel. Moreover, comparing the light efficiency of each color sub-pixel, the light efficiency of the green sub-pixel (i.e., the second color sub-pixel 21) is highest, the light efficiency of the red sub-pixel (i.e., the first color sub-pixel 11) is medium, and light efficiency of the blue sub-pixel (i.e., the third color sub-pixel 31) is lowest.

Thus, when arranging the areas of the color sub-pixels, the area of the red sub-pixel (i.e., the first color sub-pixel 11) is smaller than the area of the blue sub-pixel (i.e., the third color sub-pixel 31), so that the area of the first transparent sub-pixel 12 is larger than the area of the third transparent sub-pixel 31; the area of the red sub-pixel (i.e., the first color sub-pixel 11) is larger than the area of the green sub-pixel (i.e., the second color sub-pixel 21), so that the area of the first transparent sub-pixel 12 is smaller than the area of the second transparent sub-pixel 31. In other words, the first ratio is smaller than the third ratio, and the first ratio is larger than the second ratio.

Specifically, an area ratio is defined by the sum of the areas of the first transparent sub-pixel 12, the second transparent sub-pixel 22, the third transparent sub-pixel 32, and the transparent pixel 4 divided by the sum of the areas of the first pixel 1, the second pixel 2, the third pixel 3, and the transparent pixel 4. The area ratio is approximately estimated as follows:

The first pixel 1, the second pixel 2, the third pixel 3, and the transparent pixel 4 in the embodiment have the same area, such that the transparent pixel 4 is approximately 25% of the sum of the areas of the first pixel 1, the second pixel 2, the third pixel 3, and the transparent pixel 4. Moreover, the area of the first transparent sub-pixel 12 is approximately 50% of the area of the first pixel 1, the area of the second transparent sub-pixel 22 is approximately 75% of the area of the second pixel 2, and the area of the third transparent sub-pixel 32 is approximately 25% of the area of the third pixel 3, so that the sum of the areas of the first transparent sub-pixel 12, the second transparent sub-pixel 22, and the third transparent sub-pixel 32 is approximately 37.5% of the sum of the areas of the first pixel 1, the second pixel 2, the third pixel 3, and the transparent pixel 4. Accordingly, the area ratio is 25%+37.5%=62.5%. However, the area ratio in the embodiment is 62.5% for example, but the area ratio can be adjustable according to the designer's request. For example, the area ratio can approximately be 57.5%-67.5% by adding or subtracting 5% from 62.5%.

In more detail, the light transmittance of the display unit 10 is approximately estimated as follows: based on the above value of the area ratio, the shading area of the traces approximately reduce the area ratio by about 10%, thus the light transmittance of the display unit 10 is approximately 62.5%−10%=52.5%. However, the light transmittance in the embodiment is 52.5% for example, but the light transmittance can be changed according to the area ratio, such that the light transmittance in the invention can be approximately 47.5%-57.5%.

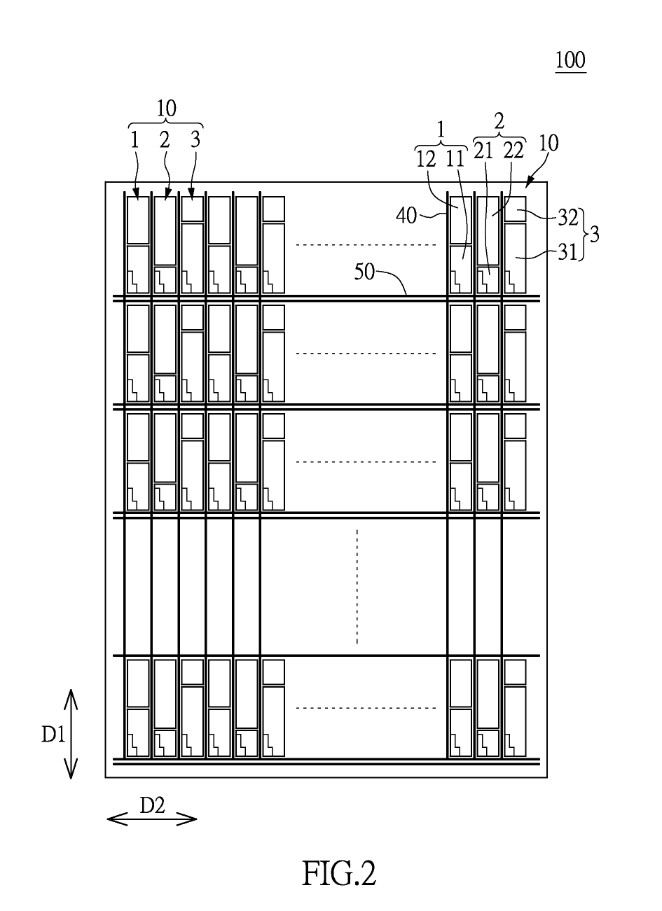

Please refer to FIG. 2, which shows another implementation of the embodiment of the invention. The difference between the display panel 100 as shown in FIGS. 2 and 1A are as follows: the display unit 10 of the display panel 100 as shown in FIG. 2 is provided without the transparent pixel 4. Specifically, at two adjacent display units 10 in any one row of the display units 10 of the display panel 100, the first pixel 1 of the right side display unit 10 is adjacent to the third pixel 3 of the other display unit 10.

Moreover, according to the estimations of the area ratio and the light transmittance about FIG. 1A, the area ratio and the light transmittance about FIG. 2 are estimated as follows. At each display unit 10 as shown in FIG. 2, the sum of the areas of the first transparent sub-pixel 12, the second transparent sub-pixel 22, and the third transparent sub-pixel 32 is approximately 50% of the sum of the areas of the first pixel 1, the second pixel 2, and the third pixel 3, so that the area ratio is approximately 50%. The area ratio can be approximately 45%-55% by adding or subtracting 5% from 50%, but the area ratio is not limited thereto. Furthermore, the light transmittance of the display unit 10 is approximately 50%−10%=40%. However, the light transmittance can be changed according to the area ratio, such that the light transmittance can approximately be 35%-45%.

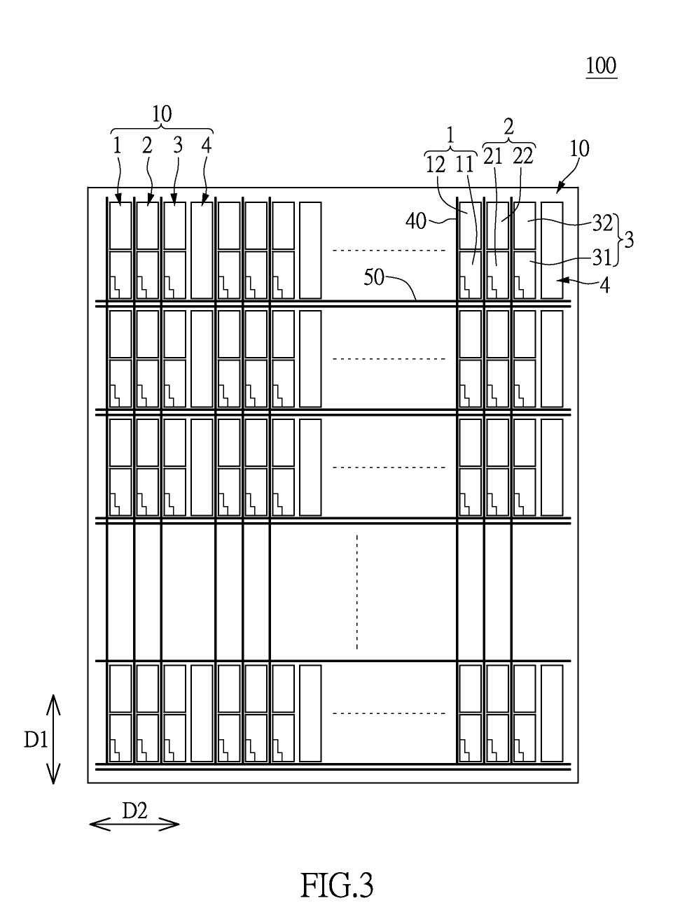

Please refer to FIG. 3, which shows the other implementation of the embodiment of the invention. The difference between the display panel 100 as shown in FIGS. 3 and 1A are as follows: the first ratio, the second ratio, and the third ratio of each display unit 10 of the display panel 100 as shown in FIG. 3 are approximately the same, and each one of the first ratio, the second ratio, and the third ratio is approximately one. Specifically, the area of the transparent pixel 4 is greater than each one of the area of the first transparent sub-pixel 12, the area of the second transparent sub-pixel 22, and the area of the third transparent sub-pixel 32.

Moreover, according to the estimations of the area ratio and the light transmittance about FIG. 1A, the area ratio and the light transmittance about FIG. 3 are estimated as follows. At each display unit 10 as shown in FIG. 3, the sum of the areas of the first transparent sub-pixel 12, the second transparent sub-pixel 22, the third transparent sub-pixel 32, and the transparent pixel 4 is approximately 62.5% of the sum of the areas of the first pixel 1, the second pixel 2, the third pixel 3, and the transparent pixel 4, so that the area ratio is approximately 62.5%. The area ratio can be approximately 57.5%-67.5% by adding or subtracting 5% from 62.5%, but the area ratio is not limited thereto. Furthermore, the light transmittance of the display unit 10 is approximately 62.5%−10%=52.5%.

In summary, the display unit of the display panel in the invention can effectively increase the light transmittance by forming the transparent sub-pixel in the pixel. The light transmittance of the display unit in the invention is more than 35% (close to 55%), a successful improvement with respect to the light transmittance of the conventional display unit about 20%. Moreover, because the color sub-pixels of the display unit respectively have different lighting properties, such that the color sub-pixel capable of higher lighting efficiency can be provided with smaller area, and the area of the corresponding transparent sub-pixel can be increased, thereby having high transmittance and high display quality.

What is claimed is:

1. A display unit of a display panel, comprising:
a first pixel having a first color sub-pixel and a first transparent sub-pixel, both arranged in one column along a first direction, wherein the first pixel has a first ratio defined by the area of the first color sub-pixel divided by the area of the first transparent sub-pixel;
a second pixel having a second color sub-pixel and a second transparent sub-pixel, both arranged in one column along the first direction, wherein the second pixel has a second ratio defined by the area of the second color sub-pixel divided by the area of the second transparent sub-pixel; and
a third pixel having a third color sub-pixel and a third transparent sub-pixel, both arranged in one column along the first direction, wherein the third pixel has a third ratio defined by the area of the third color sub-pixel divided by the area of the third transparent sub-pixel;
wherein the first pixel, the second pixel, and the third pixel are adjacent to each other and arranged in one row along a second direction, and wherein the first ratio, the second ratio, and the third ratio are different from each other.

2. The display unit of the display panel as claimed in claim 1, wherein the first direction is perpendicular to the second direction.

3. The display unit of the display panel as claimed in claim 1, wherein a length of each one of the first pixel, the second pixel, and the third pixel corresponding to the first direction is identical.

4. The display unit of the display panel as claimed in claim 1, wherein the first color sub-pixel is a red sub-pixel, the second color sub-pixel is a green sub-pixel, and the third color sub-pixel is a blue sub-pixel, wherein the area of the red sub-pixel is smaller than the area of the blue sub-pixel, and the area of the red sub-pixel is larger than the area of the green sub-pixel, the first ratio is smaller than the third ratio, and the first ratio is larger than the second ratio.

5. The display unit of the display panel as claimed in claim 1, further comprising a transparent pixel, wherein a length of the transparent pixel corresponding to the first direction is identical to the length of the first pixel, and the first pixel, the second pixel, the third pixel, and the transparent pixel are adjacent to each other and arranged in one row along the second direction.

6. The display unit of the display panel as claimed in claim 5, wherein a sum of the areas of the first transparent sub-pixel, the second transparent sub-pixel, the third transparent sub-pixel, and the transparent pixel is 57.5%-67.5% of a sum of the areas of the first pixel, the second pixel, the third pixel, and the transparent pixel.

7. The display unit of the display panel as claimed in claim 1, wherein a sum of the areas of the first transparent sub-pixel, the second transparent sub-pixel, and the third transparent sub-pixel is 45%-55% of a sum of the areas of the first pixel, the second pixel, and the third pixel.

8. A display unit of a display panel, comprising:
a first pixel having a first color sub-pixel and a first transparent sub-pixel, both arranged in one column along a first direction, wherein the first pixel has a first ratio defined by the area of the first color sub-pixel divided by the area of the first transparent sub-pixel;
a second pixel having a second color sub-pixel and a second transparent sub-pixel, both arranged in one column along the first direction, wherein the second pixel has a second ratio defined by the area of the second color sub-pixel divided by the area of the second transparent sub-pixel;
a third pixel having a third color sub-pixel and a third transparent sub-pixel, both arranged in one column along the first direction, wherein the third pixel has a third ratio defined by the area of the third color sub-pixel divided by the area of the third transparent sub-pixel; and
a transparent pixel having an area greater than each one of the area of the first transparent sub-pixel, the area of the second transparent sub-pixel, and the area of the third transparent sub-pixel;
wherein the first pixel, the second pixel, the third pixel, and the transparent pixel are adjacent to each other and arranged in one row along a second direction perpendicular to the first direction, wherein the first ratio, the second ratio, and the third ratio are the same.

9. The display unit of the display panel as claimed in claim 8, wherein each one of the first ratio, the second ratio, and the third ratio is one, a sum of the areas of the first transparent sub-pixel, the second transparent sub-pixel, the third transparent sub-pixel, and the transparent pixel is 62.5% of a sum of the areas of the first pixel, the second pixel, the third pixel, and the transparent pixel.

10. A display unit of a display panel, comprising a first pixel, a second pixel, a third pixel, and a transparent pixel, wherein the first pixel has a first color sub-pixel and a first transparent sub-pixel, both arranged in one column along a first direction, the area of the transparent pixel is greater than the area of the first transparent sub-pixel, wherein the first pixel, the second pixel, the third pixel, and the transparent pixel are adjacent to each other and arranged in one row along a second direction perpendicular to the first direction.
